(19) United States
(12) Patent Application Publication
(10) Pub. No.: US 2014/0253887 A1
(43) Pub. Date: Sep. 11, 2014

(54) CONTAMINATION PREVENTION FOR PHOTOMASK IN EXTREME ULTRAVIOLET LITHOGRAPHY APPLICATION

(71) Applicant: Applied Materials, Inc., Santa Clara, CA (US)

(72) Inventors: Banqiu WU, San Jose, CA (US); Ajay KUMAR, Cupertino, CA (US)

(73) Assignee: Applied Materials, Inc., Santa Clara, CA (US)

(21) Appl. No.: 14/199,626

(22) Filed: Mar. 6, 2014

Related U.S. Application Data
(60) Provisional application No. 61/774,351, filed on Mar. 7, 2013.

(51) Int. Cl. G03F 7/20

(52) U.S. Cl. CPC G03F 7/70733
USPC 355/30

(57) ABSTRACT

Embodiments of the present invention provide methods and apparatus for removing debris particles using a stream of charged species. In one embodiment, an apparatus for removing debris particles from a beam of radiation includes a mask station comprising a chamber body, a mask stage disposed in the mask station, and a conductive plate having an opening formed therein, wherein the conductive plate is disposed in a spaced apart relationship to the mask stage in the mask station, defining an interior volume between the mask stage and the conductive plate.

### CROSS-REFERENCE TO RELATED APPLICATIONS

This application claims benefit of U.S. Provisional Application Ser. No. 61/774,351 filed Mar. 7, 2013 (Attorney Docket No. APPM/20436L), which is incorporated by reference in its entirety.

### BACKGROUND

1. Field

Embodiments of the present invention generally relate to methods and apparatus for preventing particle contamination. Particularly, embodiments of the present invention provide methods and apparatus for protecting photomasks and/or substrates from contamination during lithography.

2. Description of the Related Art

In the manufacture of integrated circuits (IC), or chips, patterns representing different layers of the chip are created by a chip designer. A series of reusable masks, or photomasks, are created from these patterns in order to transfer the design of each chip layer onto a semiconductor substrate during the manufacturing process. Mask pattern generation systems use precision lasers or electron beams to image the design of each layer of the chip onto a respective mask. The masks are then used much like photographic negatives to transfer the circuit patterns for each layer onto a semiconductor substrate. These layers are built up using a sequence of processes and translate into the tiny transistors and electrical circuits that comprise each completed chip. Thus, any defects in the mask may be transferred to the chip, potentially adversely affecting performance. Defects that are severe enough may render the mask completely useless. Typically, a set of 15 to 30 masks is used to construct a chip and can be used repeatedly.

With the shrink of critical dimensions (CD), present optical lithography is approaching a technological limit at the 45 nanometer (nm) technology node. Next generation lithography (NGL) is expected to replace the conventional optical lithography method, for example, in the 32 nm technology node and beyond. There are several NGL candidates, such as extreme ultraviolet (EUV) lithography (EUVL), electron projection lithography (EPL), ion projection lithography (IPL), nano-imprint, and X-ray lithography. Among these, EUVL is the most likely successor due to the fact that EUVL has most of the properties of optical lithography, which is more mature technology as compared with other NGL methods.

Typically, one photomask, e.g., a reticle, may be repeatedly used to reproducibly print thousands of substrates. Typically, a photomask, e.g., a reticle, is typically a glass or a quartz substrate giving a film stack having multiple layers, including a light-absorbing layer and an opaque layer disposed thereon. While performing the photolithography process, a pellicle is used to protect the reticle from particle contamination. Pellicle is a thin transparent membrane which allows lights and radiation to pass therethrough to the reticle. The pellicle is a relatively inexpensive, thin, transparent, flexible sheet, which is stretched above and not touching the surface of the mask. Pellicles provide a functional and economic solution to particulate contamination by mechanically separating particles from the mask surface. The mask is transported and used for lithographic exposure with the pellicle in place. When a mask is used for exposure, with the pellicle in position above the mask, only the details of the mask's focal plane itself are printed. Particulate material located on the pellicle surface is maintained outside of the focal plane of projection. As a result, particulate material is not printed. When the pellicle eventually becomes damaged or too dirty to use, the mask is removed to a workshop, and the pellicle is replaced.

However, in EUV lithography, conventional pellicles are not suitable for protecting masks during lithography process because materials used to form pellicles are often opaque to EUV light. Furthermore, as the sizes of the features on the reticle are becoming increasingly small, defects, such as particles, in any sizes may adversely affect transferring of the features to the substrate during the lithography process without protection of the pellicles. In one example, in EUV lithography for 22 nm technology node, particles as small as 18 nm must be removed and kept away from the reticle so as to pertain high transfer accuracy to the substrate for manufacturing integrated circuit. Replacement of pellicles is not yet developed.

Therefore, there is a need for apparatus and methods for protecting masks during lithography.

### SUMMARY

Embodiments of the present invention generally provide apparatus and methods for removing particle contamination from a photomask during a lithography process. Particularly, embodiments of the present invention provide methods and apparatus for removing debris particles from the photomask by establishing an electrical potential close to the photomask surface to repel particles away from the photomask. In one embodiment, an apparatus for removing debris particles from a beam of radiation includes a mask station comprising a chamber body, a mask stage disposed in the mask station, and a conductive plate having an opening formed therein, wherein the conductive plate is disposed in a spaced apart relationship to the mask stage in the mask station, defining an interior volume between the mask stage and the conductive plate.

In another embodiment, a system for performing a lithography process includes a mask station comprising a chamber body, a mask stage disposed in the chamber body, a conductive plate having an opening formed therein coupled to sidewalls of the chamber body, wherein the conductive plate is disposed in a spaced apart relationship to the mask stage in the mask station, defining an interior volume between the mask stage and the conductive plate, and a radiation system configured to project a beam of radiation passing through the opening of the conductive plate toward the mask stage.

In yet another embodiment, a method for removing debris particles in a beam of radiation includes providing a photomask disposed on a mask stage in a mask station, providing a beam of radiation passing through a conductive plate disposed in the mask station toward the photomask, applying a power to the conductive plate to create an electrical potential between the photomask and the conductive plate, and removing debris particles from the beam of radiation by repelling debris particles away from the photomask using electrostatic force outward from the mask station.

### BRIEF DESCRIPTION OF THE DRAWINGS

So that the manner in which the above recited features of embodiments of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates a lithography system in accordance with one embodiment of the present invention.

FIG. 2 schematically illustrates an enlarged view of a conductive plate disposed close to a photomask and a particle removal station of the lithography system of FIG. 1.

FIG. 3 schematically illustrates a photomask having multiple film stack disposed thereon in accordance with one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally provide apparatus and methods for removing particle contamination from a photomask during a lithography process. Particularly, embodiments of the present invention provide methods and apparatus for removing debris particles from the photomask by establishing an electrical field close to the photomask surface to repel particles away from the photomask. In one embodiment, a conductive plate is disposed adjacent to the photomask so as to create an electrode field close to the photomask substrate. The electrode field may assist repelling particles, ions or charges away from the photomask surface, thereby maintaining cleanliness of the photomask surface.

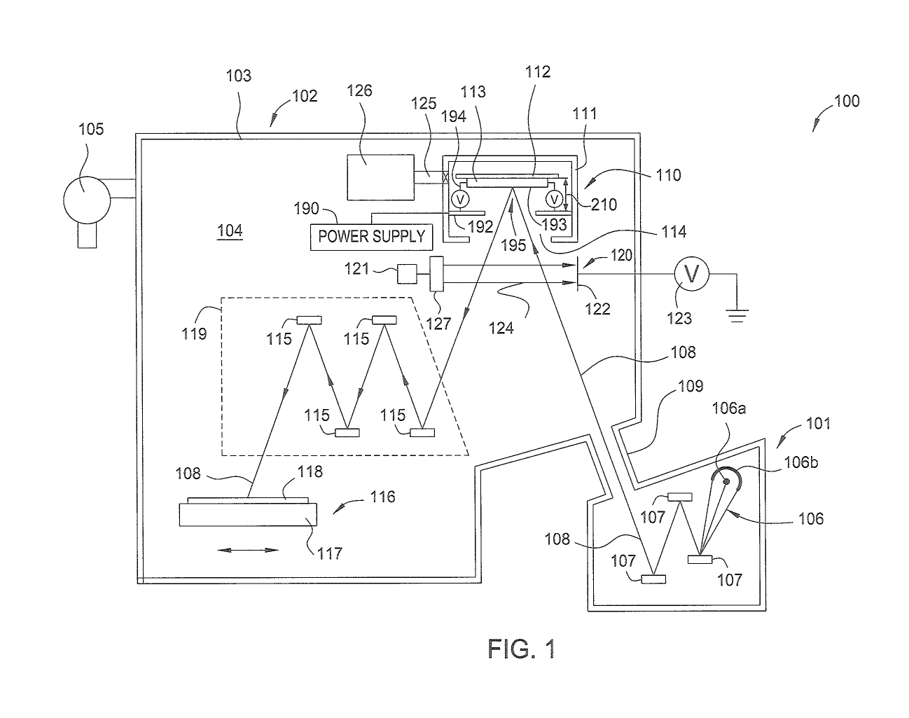

FIG. 1 schematically illustrates a lithography system 100 in accordance with one embodiment of the present invention. The lithography system 100 generally comprises a radiation system 101 configured to generate a beam of radiation 108 to be used during a lithography process. The lithography system 100 further comprises a lithography apparatus 102 in connection with the radiation system 101 via a wave train 109.

The radiation system 101 generally comprises a radiation source 106 and a projection system 107. In one embodiment, the radiation source 106 may comprise a laser produced plasma 106a and a collection mirror 106b. In one embodiment, the radiation system 101 may be configured to generate extreme ultraviolet (EUV) radiation with a wavelength in the range of 5 nm to 20 nm. The radiation system 101 is configured to project a beam of radiation 108 towards the lithography apparatus 102 for a lithographic process.

The lithography apparatus 102 comprises a body 103 defining an inner volume 104. During process, the inner volume 104 may be vacuumed using a pumping system 105 as processing in a vacuum state is often utilized to prevent particle contamination. The lithography apparatus 102 further comprises a mask station 110, a projection system 119, a substrate stage 116, and a particle removal station 120, which are disposed in the inner volume 104.

The mask station 110 is configured to position a photomask 113, e.g., a reticle, which is configured to receive and reflect the beam of radiation 108 to the projection system 119. The photomask 113 has a pattern formed thereon and the pattern is reflected in the beam of radiation 108 by the photomask 113. The projection system 119 is configured to project the beam of radiation 108 and convey the pattern to a substrate 118 positioned on the substrate stage 116 which is configured to precisely position the substrate 118. The substrate 118 utilized here may be a semiconductor substrate fabricated from crystalline silicon, doped silicon, or composited silicon substrate including one or more nonconductive materials, dielectric materials or conductive layers disposed thereon depending on the application. The substrate 118 is not limited to any particular size or shape. The substrate 118 can be a round wafer having a 200 mm diameter, a 300 mm or a 450 mm diameter. The substrate can also be any polygonal, square, rectangular, curved or otherwise non-circular workpiece, such as a glass substrate as needed.

The particle removal station 120 is disposed on a path of the beam of radiation 108 and configured to remove debris particles travelling along the beam of radiation 108. In one embodiment, the particle removal station 120 is positioned near the mask station 110 intersecting the input and output path of the beam of radiation 108 to and from the photomask 113.

The mask station 110 comprises a chamber body 111 having a shutter opening 114 configured to transmit the beam of radiation 108 during processing. The photomask 113 is positioned on a mask stage 112 configured to position photomask 113 to align with the beam of radiation 108 and the projection system 119. The mask stage 112 may be moved in X-Y directions or be moved relative to the beam of radiation 108 so as to ensure features/structures on the photomask 113 being exposed to beam of radiation 108 as needed during a lithography process. In case of EUV lithography, the photomask 113 is directly exposed to the beam of radiation 108 and the ambient of the inner volume 104 without any protection because all materials are opaque to EUV wavelength. However, an optional shutter may be disposed in the shutter opening 114 and be closed while not processing.

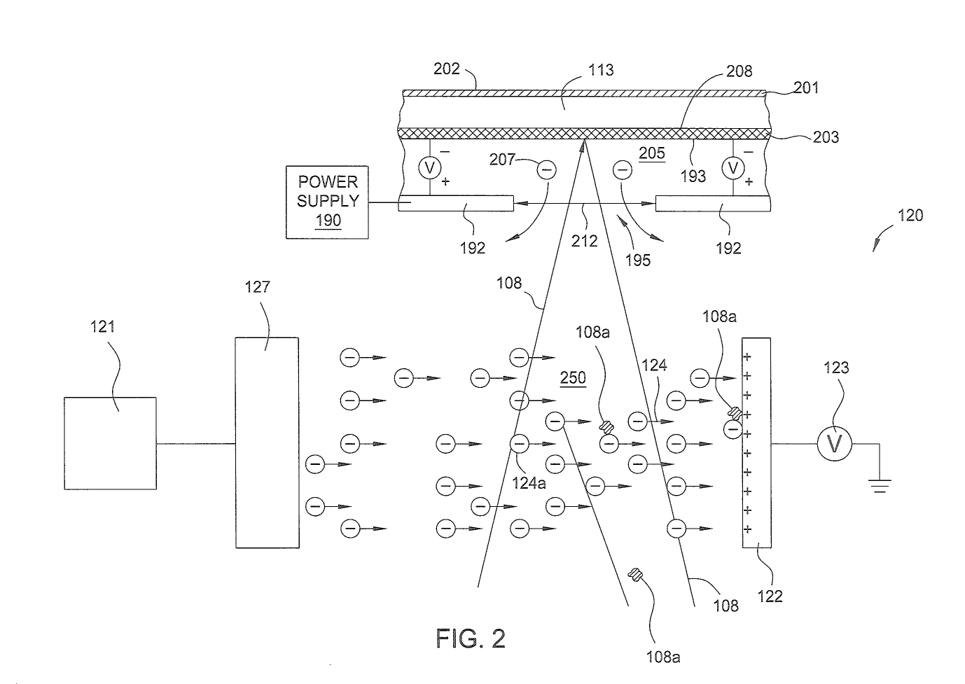

A conductive plate 192 is disposed in the mask station 110 spaced apart from a front surface 193 of the photomask 113 in a parallel arrangement with the photomask 113. The conductive plate 192 may be in form of a metal plate, a metal ring, or any suitable conductive structure having an opening 195 that allows the beam of radiation 108 passing therethrough to the front surface 193 of the photomask 113. The conductive plate 192 may be coupled to sidewalls of the chamber body 111 and is removable from the mask station 110 for periodic cleaning. In one embodiment, the conductive plate 192 is positioned at a distance 210 between about 10 mm and about 30 mm to the mask stage. A power source 190 is coupled to the conductive plate 192 by a circuit arrangement 194. As the photomask 113 may often have conductive materials disposed thereon, during operation, the conductive plate 192 and conductive materials disposed on the photomask 113 may each act as electrodes that may generate electrical field therebetween upon applying a power. A voltage V may be applied to the conductive plate 192, establishing an electric field creating an electric potential, which may repel, e.g., push, charged particles away from the surface 193 of the photomask 113. By doing so, cleanliness of the front surface 193 of the photomask 113 may be maintained. In one embodiment, the voltage V may be applied to the conductive plate 192 for between about 50 Volts and about 500 Volts. The photomask 113 may be ground as needed. Details regarding the structures and mechanism of the conductive plate 192 to the photomask 113 will be further described below with referenced to FIG. 2.

The mask station 110 may further comprise a mask transfer mechanism 125 configure to transfer the photomask 113 to and from a mask storage 126, where different masks may stored in a sealed condition.

The projection system 119 comprises a plurality of mirrors 115 configured to reflect the beam of radiation 108 towards the substrate 118. The projection system 119 may comprise up to 10 mirrors. The projection system 119 may comprise a projecting column (not shown) configured to project the beam of radiation 108 from the plurality of mirrors 115 to the substrate 118 at a desired ratio and a desired location.

The substrate stage 116 generally comprises a substrate support 117 which is configured to support, translate and rotate the substrate 118 to enable the beam of radiation 108 to be projected to a plurality of dies.

The particle removal station 120 is configured to remove any debris particles travelling within the beam of radiation 108 to protect the mask 113, the mirrors 115 and the substrate 118. The particle removal station 120 may be positioned anywhere in the path of the beam of radiation 108.

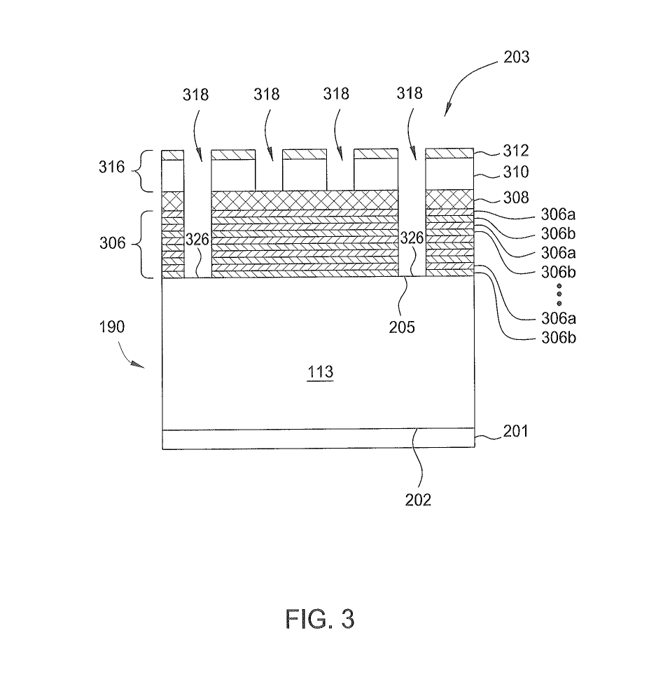

FIG. 2 schematically illustrates an enlarged view of the conductive plate 192 disposed in the mask station 110 adjacent to the particle removal station 120 of FIG. 1. The mask station 110 includes the photomask 113 disposed thereon. The photomask 113 includes a backside conductive layer 201 disposed on a back surface 202 of the photomask 113 and a film stack 203 disposed on a front surface 208 of the photomask 113. The film stack 203 may include at least one conductive layer disposed therein. Details of the film stack 203 that may be utilized to be disposed on the photomask 113 will be further discussed below with referenced to FIG. 3.

The conductive plate 192 disposed in the mask station 110 may comprise a substantially flat plate which may be disposed against or coupled to sidewalls of the chamber body 111. The conductive plate 192 may be disposed at a spaced relationship to the front surface 193 of the photomask 113, defining an interior volume 205 between the photomask 113 and the conductive plate 192. The conductive plate 192 may be made of a variety of materials compatible with process. In one embodiment, the conductive plate 192 is a conductive ring fabricated tantalum coating materials, gold containing materials, stainless steel, or other suitable materials.

The conductive plate 192 may have one or more openings 195 that define a desired open area in the conductive plate 192. This open area allows the beam of radiation 108 to be passed therethrough without optical or electrical interference. The open area 150 controls the amount of ions/charges 207 that may possibly and adversely sneak into the mask station 110 in the interior volume 205 adjacent to the photomask 113. The opening 195 may be circular, square, rectangular, or other geometric from. In one embodiment, the opening 195 the conductive plate 192 has a width 212 between about 140 mm and about 160 mm

During processing, power may be supplied from the power source 190 to the conductive plate 192 so as to develop an electrical potential across the interior volume 205 defined between the photomask 113 and the conductive plate 192. The electrical potential repels charged particles 207 such as ions, particles or other contamination effectively pushing them away from and preventing them from entering into the interior volume 205, thereby maintaining a particle/contamination free environment in the interior volume 205. Thus, by applying an appropriate power level to establish an electric field between the photomask 113 and the conductive plate 192, an electric potential as obtained may efficiently minimize the amount of charged particles 207, such as ions or other contamination, that may possible reach to the surface 193 of the photomask 113, thereby maintaining cleanliness of the photomask 113 in a more controlled manner. This reduces possibility of contamination to the photomask 113, thus resulting in improved quality and lifetime of photomask 113.

According to one embodiment of the invention, the conductive plate 192 may comprise a number of zones with different configurations including various geometries (e.g., multiple plate sizes or shapes), so different zones may have different potential bias as needed to repel charged particles 207 with different degree of polarity, sizes, molecular weight or characteristic away from the photomask 113. By providing different combinations of zone configurations, materials and/or potential bias, the electrical potential as created may be modified in a localized manner, allowing customization of electrical characteristics, such as different repelling energy created within the interior volume 205 and so on, during process.

In one embodiment, a voltage V may be applied to the conductive plate 192, establishing an electric field creating an electric potential, which may repel, e.g., push, charged particles away from the surface 193 of the photomask 113. The voltage V may be applied to the conductive plate 192 for between about 50 Volts and about 500 Volts.

The particle removal station 120 comprises a charged species source 127 and a collecting plate 122. The charged species source 127 is connected to a power source 121 and is configured to generate a stream of charged species 124 comprising charged species 124a. The collecting plate 122 is then configured to receive the stream of charged species 124 from the charged species source 127. The collecting plate 122 is connected to a power source 123 which may provide an electrical potential in operation to attract the charged species 124. A power may be applied to the collecting plate 122 through the power source 123 so as to provide electrical power to the collecting plate 122 to generate a charged surface having polarity opposite to the charged species 124a. The stream of charged species 124 is attracted to and collected by the collecting plate 122 without creating interference to other devices, such as optics in the system, that are sensitive to electric field. In one embodiment, the charged species source 127 and the collecting plate 122 may be positioned in front of a mask holder, any mirrors, or a radiation source. The collecting plate may be charged at a potential between about 200 volts to about 400 volts.

During processing, the particle removal station 120 may be positioned in a parallel arrangement defining a bounded passage 250 that allows the beam of radiation 108 to pass therethrough without optical or electrical interference. The charged species source 127 and the collecting plate 122 may each be positioned on opposite sides of the bounded passage 250. The stream of charged species 124 is configured to flow and move from the charged species source 127 toward the collecting plate 122 when charged/biased. The stream of the charged species 124 intersects the beam of radiation 108, absorbing debris particles 108a presented in the beam of radiation 108 using electrostatic force. The electrostatic force removes debris particles 108a from the beam of radiation 108, thus, preventing the debris particles 108a from entering into the interior volume 205, contaminating the photomask 113, passing close to the substrate 118 being processed (depicted in FIG. 1), or any devices in the path of the beam of radiation 108. The absorbed debris particles 108a then travel with the stream of charged species 124, biasing toward the collecting plate 122 and eventually collected by the collecting plate 122. Furthermore, when the charged particles 207 is repelled from the interior volume 205 away from the photomask 113 by the conductive plate 192, the charged particles 207 may then travel to the bounded passage 250 and be collected by the collecting plate 122.

The charged species 124a may be electrons, ions of positive or negative charges. In one embodiment, the charged species source 127 may be a corona charge generator, a thermal emitter, or an ion generator. Some gases, such as inert gas including He or Ar, or oxygen containing gas may be utilized to assist generating charged species as needed. In some cases, some contamination may be out-gassed from the substrate 118 during the exposure process. For example, when a photoresist layer is present on the substrate 118, carbon containing contamination or other pollutants may be released or out-gassed from the substrate traveling close to the mirrors 115 or close to the particle removal station 120. In this particular embodiment, an oxygen containing gas may be supplied, forming oxygen ions or oxygen charges to react with the carbon containing contamination or other pollutants, pumping from the lithography system 100 through the pumping system 105.

Although only one particle removal station 120 is described in the lithography system 100, more similar particle removal stations may be positioned in suitable positions, such as in front of any mirrors 115, and within the radiation source 106 as needed.

FIG. 3 depicts details of the film stack 203 that may be disposed on the photomask 113. The photomask 113 includes the film stack 203 disposed on the photomask 113 having desired features 318 formed therein. As the exemplary embodiment depicted in FIG. 3, the photomask 113 may be a quartz substrate (i.e., low thermal expansion silicon dioxide (SiO₂)) layer. The photomask 113 has a rectangular shape having sides between about 5 inches to about 9 inches in length. The photomask 113 may be between about 0.15 inches and about 0.25 inches thick. In one embodiment, the photomask 113 is about 0.25 inches thick. An optional conductive layer 201, for example a chromium containing layer, such as a chromium nitride (CrN) layer may be disposed to the back surface 202 of the photomask 113 as needed.

A EUV reflective multi-material layer 306 is disposed on the photomask 113. The reflective multi-material layer 306 may include at least one molybdenum layer 306a and a silicon layer 306b. Although the embodiment depicted in FIG. 3 shows five pairs of molybdenum layer 306a and a silicon layer 306b (alternating molybdenum layers 306a and the silicon layers 306b repeatedly formed on the photomask 113), it is noted that number of molybdenum layers 306a and the silicon layers 306b may be varied based on different process needs. In one particular embodiment, forty pairs of molybdenum layers 306a and the silicon layers 306b may be deposited to form the reflective multi-material layer 306. In one embodiment, the thickness of each single molybdenum layer 306a may be controlled at between about 1 nm and about 10 nm, such as about 2.7 nm, and the thickness of the each single silicon layer 306b may be controlled at between about 1 nm and about 10 nm, such as about 4.1 nm. The reflective multi-material layer 306 may have a total thickness between about 10 nm and about 500 nm. The reflective multi-material layer 306 may have an EUV light reflectivity of up to 70% at 13.5 nm wavelength. The reflective multi-material layer 306 may have a total thickness between about 70 nm and about 500 nm.

Subsequently, a capping layer 308 is disposed on the reflective multi-material layer 306. The capping layer 308 may be fabricated by a metallic material, such as ruthenium (Ru) material, zirconium (Zr) material, or any other suitable material. In the embodiment depicted in FIG. 3, the capping layer 308 is a ruthenium (Ru) layer. The capping layer 308 has a thickness between about 1 nm and about 10 nm.

An absorber layer 316 may then be disposed on the capping layer 308. The absorber layer 316 is an opaque and light-shielding layer configured to absorb portion of the light generated during the lithography process. The absorber layer 316 may be in form of a single layer or a multi-layer structure, such as including a self-mask layer 312 disposed on a bulk absorber layer 310, as the embodiments depicted in FIGS. 3. In one embodiment, the absorber layer 316 has a total film thickness between about 50 nm and about 200 nm. The total thickness of the absorber layer 316 advantageously facilitates meeting the strict overall etch profile tolerance for EUV masks in sub-32 nm technology node applications.

In one embodiment, the bulk absorber layer 310 may comprise tantalum-based materials with essentially no oxygen, for example tantalum silicide based materials, such as TaSi, nitrogenized tantalum boride-based materials, such as TaBN, and tantalum nitride-based materials, such as TaN. The self-mask layer 312 may be fabricated from a tantalum and oxygen-based materials. The composition of the self-mask layer 312 corresponds to the composition of the bulk absorber layer 310 and may comprise oxidized and nitrogenized tantalum and silicon based materials, such as TaSiON, when the bulk absorber layer 310 comprises TaSi or TaSiN; tantalum boron oxide based materials, such as TaBO, when the bulk absorber layer 310 comprises TaBN; and oxidized and nitrogenized tantalum-based materials, such as TaON, when the bulk absorber layer 310 comprises TaN. The openings (i.e., features) 318 are formed in the film stack 203 exposing the underlying surface 326 of the photomask 113 to complete forming the desired structures in the film stack 203.

Even though only lithography process is described in accordance with the present invention, embodiments of the present invention may be applied to any suitable process and in any suitable processing tools that requires removal of particle contamination in a path of energy or fluid transmission.

Thus, a method and apparatus for removing contamination or particles from a photomask during a lithography process are provided. The methods and apparatus advantageously prevent contamination or debris particles from entering into a region close to the photomask. Furthermore, the contamination or debris particles may be absorbed and attacked by a collecting plate, thereby efficiently removing contamination or debris particles from the processing system. Accordingly, the method and the apparatus provided herein advantageously facilitate fabrication of photomasks with desired degree of cleanliness which is suitable for utilization in EUV technologies.

While the foregoing is directed to embodiments of the present invention, other and further embodiments of the invention may be devised without departing from the basic scope thereof, and the scope thereof is determined by the claims that follow.

What is claimed is:

1. A method for removing debris particles in a beam of radiation, comprising:
providing a photomask disposed on a mask stage in a mask station;
providing a beam of radiation passing through a conductive plate disposed in the mask station toward the photomask;
applying a power to the conductive plate to create an electrical potential between the photomask and the conductive plate; and
removing debris particles from the beam of radiation by repelling debris particles away from the photomask using electrostatic force outward from the mask station.

2. The method of claim 1, further comprising:
flowing a stream of charged species from a charged species source to a collecting plate disposed adjacent to the mask station;
charging the collecting plate with electrical potential opposite to the charged species from a charged species source, and
attracting debris particles from the beam of radiation with the charged species to the collecting plate.

3. The method of claim 2, further comprising:
attracting debris particles repelled from the mask station to the collecting plate.

4. The method of claim 1, wherein applying the power to the conductive plate further comprises:
applying a power between about 50 volts and about 500 volts to the conductive plate.

5. The method of claim 1, wherein the beam of radiation is a beam of extreme ultraviolet waves.

6. The method of claim 1, wherein the beam of radiation is emitted from a radiation system disposed adjacent to the conductive plate.

7. The method of claim 6, wherein the beam of radiation is emitted toward the photomask through the openings formed in the conductive plate.

8. The method of claim 1, wherein the conductive plate is a conductive ring fabricated from tantalum coating materials, gold containing materials and stainless steel.

9. The method of claim 7, wherein the opening of the conductive plate has a width between about 140 mm and about 160 mm.

10. The method of claim 7, wherein the opening of the conductive plate allows open communication of the photomask to an interval defined between the charged species source and the collecting plate.

11. The method of claim 1, wherein the conductive plate is removable from the mask station.

12. The method of claim 1, wherein a circuit arrangement is coupled between the conductive plate and the photomask disposed on the mask stage in the mask station.

13. A method for removing debris particles in a beam of radiation, comprising:
providing a beam of radiation passing through a conductive plate disposed in a mask station toward ae photomask disposed in the mask station;
applying a power to the conductive plate to create an electrical potential between the photomask and the conductive plate;
removing debris particles from the beam of radiation by repelling debris particles away from the photomask using electrostatic force outward from the mask station; and
attracting debris particles repelled from the mask station to a collecting plate disposed adjacent to the mask station.

14. The method of claim 13, further comprising:
flowing a stream of charged species from a charged species source to a collecting plate disposed adjacent to the mask station;
charging the collecting plate with electrical potential opposite to the charged species from a charged species source, and
attracting debris particles from the beam of radiation with the charged species to the collecting plate.

15. The method of claim 13, wherein the conductive plate includes openings that allow open communication of the photomask to the beam of radiation emitted through the opening to the photomask.

16. The method of claim 13, wherein the conductive plate is a conductive ring fabricated from tantalum coating materials, gold containing materials and stainless steel.

17. The method of claim 15, wherein the opening of the conductive plate has a width between about 140 mm and about 160 mm.

18. The method of claim 15, wherein the beam of radiation is projected from a radiation system passing through the opening of the conductive plate toward the mask station.

19. The method of claim 14, wherein the collecting plate is positioned in a parallel arrangement opposite to the charged species source.

20. The method of claim 14, wherein charged species source is configured to dispense electrically charged species, and the collecting plate is configured to be electrically biased opposite to the charged species from the charged species source
